(19) United States
(12) Patent Application Publication
(10) Pub. No.: US 2021/0336116 A1
(43) Pub. Date: Oct. 28, 2021

(54) THERMOELECTRIC ARRAY

(71) Applicant: The Aerospace Corporation, El Segundo, CA (US)

(72) Inventor: Song-Jun HU, Redondo Beach, CA (US)

(73) Assignee: The Aerospace Corporation

(21) Appl. No.: 16/860,658

(22) Filed: Apr. 28, 2020

(51) Int. Cl. H01L 35/02; H01L 35/32

(52) U.S. Cl. CPC H01L 35/02; H01L 35/32

(57) ABSTRACT

An apparatus includes a thermoelectric generator and a lens. The thermoelectric generator includes a hot plate, and is configured to convert heat directly into electrical energy. The lens faces the sun on one side and faces the hot plate on the other side. The lens is configured to concentrate heat from the sun and onto the hot plate.

### FIELD

The present invention relates to a thermoelectric array, and more particularly, to a thermoelectric array configured to convert heat flux directly into electrical energy.

### BACKGROUND

The current state of the art, which are being used in satellites, include space grade photovoltaics. This photovoltaics are III-V multi-junction solar cells.

However, photovoltaics have a low tolerance to radiation and temperature. For example, typical operating temperature for a photovoltaic is approximately 40 to 60 degrees Celsius for geostationary Earth orbit (GEO). Further, with increase in temperature, the voltage decreases, e.g., the operating voltage of the bus is affected. Aside from being radiation and temperature sensitive, these cells are extremely expensive to develop. For example, the average cost of per solar cell is approximately $400.00 to $1,200.00 USD.

Thus, an improved thermoelectric array is needed.

### SUMMARY

Certain embodiments of the present invention may provide solutions to the problems and needs in the art that have not yet been fully identified, appreciated, or solved by current electric generator technologies. For example, some embodiments of the present invention pertain to a thermoelectric array configured to convert heat flux directly into electrical energy.

In an embodiment, an apparatus includes a thermoelectric generator and a lens. The thermoelectric generator includes a hot plate, and is configured to convert heat directly into electrical energy. The lens faces the sun on one side and faces the hot plate on the other side. The lens is configured to concentrate heat from the sun and onto the hot plate.

### BRIEF DESCRIPTION OF THE DRAWINGS

In order that the advantages of certain embodiments of the invention will be readily understood, a more particular description of the invention briefly described above will be rendered by reference to specific embodiments that are illustrated in the appended drawings. While it should be understood that these drawings depict only typical embodiments of the invention and are not therefore to be considered to be limiting of its scope, the invention will be described and explained with additional specificity and detail through the use of the accompanying drawings, in which:

FIG. 1 is a diagram illustrating a thermoelectric generator, according to an embodiment of the present invention.

FIG. 2 is a diagram illustrating a thermoelectric array, according to an embodiment of the present invention.

FIG. 3 is a diagram illustrating a thermoelectric generator, according to an embodiment of the present invention.

FIG. 4 is a diagram illustrating a multiple views (a)-(b) of thermoelectric generator, according to an embodiment of the present invention.

### DETAILED DESCRIPTION OF THE EMBODIMENTS

Some embodiments of the present invention pertain to a thermoelectric array composed of a plurality of thermoelectric couples. The thermoelectric couples are semiconductor materials (PN) configured to convert heat flux directly into electrical energy by way of a phenomenon called a Seebeck effect. The thermoelectric couples are connected in series and parallel to form a thermoelectric array that produces a certain voltage and current under a temperature difference (ΔT) between the hot side (plate) and cold side (plate).

The cold plate in some embodiments serves as structural support of, and also serves as the cold side of, the thermoelectric array. Because the cold plate has a larger surface area than the hot plate, the heat is dissipated into space at a faster rate. This allows for the temperature difference (ΔT) between the hot plate and cold plate of the thermoelectric array to be higher. It should be noted that the higher the temperature difference (ΔT), the higher the power generated. The cold plate and hot plate, both of which are composed of aluminum honeycomb allows for structural integrity and weight savings.

Thermoelectric array also includes a concentrator lens configured to increase the amount of sun energy on the hot side (or hot plate) of thermoelectric array. The concentrator lens can be scaled up or down depending on the desired temperature. The area of the concentrator lens and the area of the cold plate scale relative to the amount of concentration desired. For example, a 3× (or three times) concentrator lens would be the area of the hot plate multiplied by three.

In certain embodiments, the cold plate is a rigid aluminum plate with a black high-temperature ceramic coating, and the hot plate is a high-temperature ceramic. The thermoelectric couples are interconnected together and sandwiched between the hot and cold plate, and have junctions composed of tin selenide. It should be appreciated that tin selenide has a ZT number of approximately 2.6 at 650 degrees Celsius (along the b-axis). ZT number is defined as a figure of merit, which describes how effective the material is at transforming thermal energy into electric current. In some embodiments, the higher the ZT number, the more efficient the thermoelectric number. Further, tin selenides are materials that include non-toxic and economical earth-abundant elements, and are low cost compared to that of solar cells. Also, tin selenides are temperature resistant and can withstand heat up to 700 degrees Celsius.

Also, in some additional embodiments, the thermoelectric couples are connected via a copper interconnect (or harness) to form the larger thermoelectric array.

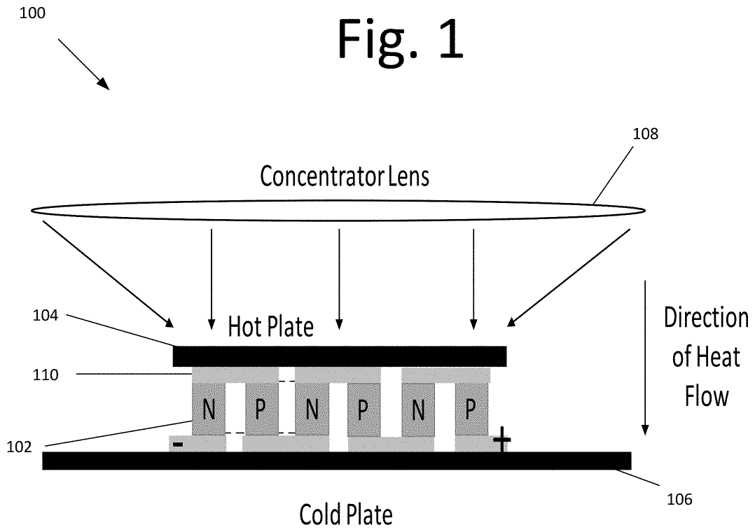

FIG. 1 is a diagram illustrating a thermoelectric generator 100, according to an embodiment of the present invention. In an embodiment, thermoelectric generator 100 includes a thermoelectric couple 102 (made of NP junction) sandwiched between a hot plate 104 and a cold plate 106. On the other side of hot plate 102 is a concentrator lens (hereinafter “lens”) 108. In certain embodiments, lens 108 may be composed of glass, and may be configured to generate (or concentrate) heat onto hot plate 104. Cold plate 106 is composed of a substrate that is different from the material in a terrestrial thermoelectric generator. For example, the substrate in some embodiments is a ceramic coated aluminum honeycomb. Depending on the embodiment, the ceramic coated aluminum honeycomb remains electrically insulative. However, unlike a bulk piece of ceramic in terrestrial applications, the honeycomb aspect allows for weight savings and structural integrity to reduce launch cost and with stand launch environment.

Traditionally, in terrestrial applications, concentrator lenses face a heat generating device. However, for space applications, lens 108 faces the sun, concentrating the heat from the sun onto hot plate (or hot side) 104. If, for example, lens 108 was not used, the sun by itself could not generate enough power to make thermoelectric generator 100 worthwhile. Cold plate 106 may be adjacent to, or may be facing, deep space, and radiates rejected heat into deep space. By increase the size of cold plate 106, the rate of heat dissipation is increased and control of the operating temperature of the thermoelectric generator 100 is realized. The ability to control the operating temperature of the thermoelectric generator 100 is important because the thermoelectric material has an optimum operating temperature. By increasing or decreasing the size of cold plate 106, the thermoelectric generator 100 can be designed to operate at a specific temperature

Some embodiments increase the size (or area) of cold plate 106 with respect to thermoelectric couple 102. By increasing the size of cold plate 106, the temperature difference (ΔT) between hot plate 104 and cold plate 106 is increased. Because the temperature difference (ΔT) is increased, the efficiency and the overall temperature of thermoelectric generator 100 is easily controlled. The efficiency of thermoelectric generator 100 may be increased in two ways. For example, by increasing the area of cold plate 106, the area from which the heat can dissipate out of is increased, thereby increasing the ΔT. Further, the heat dissipation of thermoelectric generator 100 is also increased, allowing a maximum ΔT to be achieved while preventing the hot plate 104 to reach above melting temperatures. By sizing cold plate 106 to the thermoelectric material's optimum temperature, the maximum efficiency of that material is realized.

On both sides of thermoelectric couple 102 are interconnects 110. These interconnects 110 are composed of copper. Depending on the embodiment, interconnects 110 may be printed directly onto cold plate 106, and thermoelectric couples 102 may be welded or soldered via an automated process. As would be appreciated, the semiconductor material (N, P) within thermoelectric couple 102 generates the electricity from the heat, and interconnects 110 conducts electric flow between material forming the electric current.

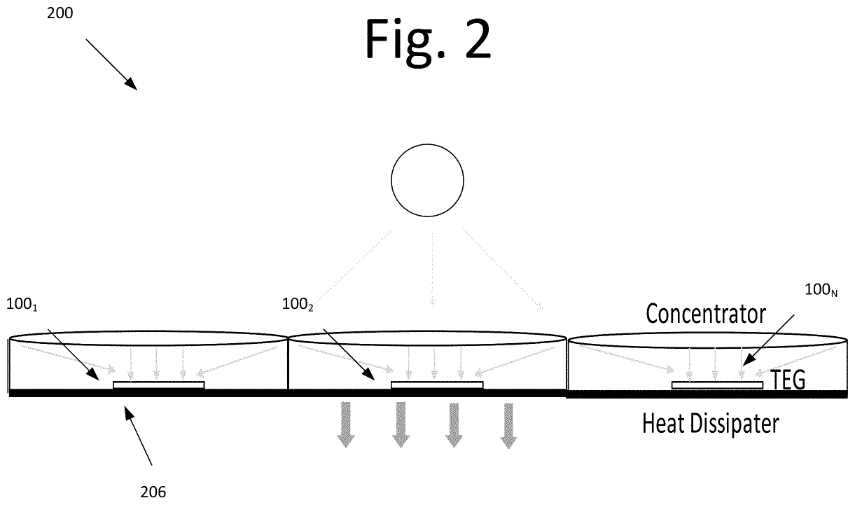

FIG. 2 is a diagram illustrating a thermoelectric array 200, according to an embodiment of the present invention. In some embodiments, a plurality of thermoelectric generators 100₁ . . . 100_{N} may form a thermoelectric array 200. Depending on the embodiment, cold plate 206 may comprise of sufficient area to include each thermoelectric generator 100₁ . . . 100_{N}. In other words, a single sheet or panel may be used as cold plate 206 to encompass thermoelectric generators 100₁ . . . 100_{N}. Such a configuration decreases the manufacturing costs of the thermoelectric generator 100. Further, as shown in FIG. 2, lens 202 may be placed above corresponding thermoelectric generators 100₁ . . . 100_{N}. This way, heat from the sun is concentrated on the hot side (or plate).

Returning to FIG. 1, in some embodiments, thermoelectric generator 100 is a solid-state device that uses heat as energy by creating a current through the conversion of heat flux. In other words, the solid-state device converts heat flux directly into electrical energy by way of a Seebeck effect.

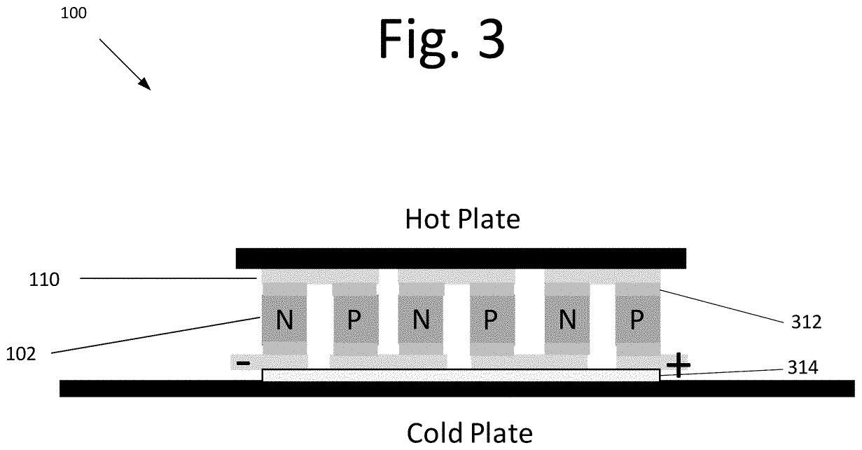

FIG. 3 is a diagram illustrating a thermoelectric generator 300, according to an embodiment of the present invention. In some embodiments, a high temperature resistant adhesive 314 is used to bond cold plate 106 to interconnects 110. High temperature may be defined as calculations have been performed to show that cold side (or cold plate 106) can reach temperatures around 400K. For instance, a resistant adhesive 314 may need to withstand at least that temperature without deteriorating. Additionally, silver and/or copper based alloys 312 can be used for soldering interconnects 110, or interconnects 110 can be welded to thermoelectric couple 102. These alloy-based solders in some embodiments withstand high temperatures above 700 C. Note that traditional solders used in electronics have low temperature tolerance.

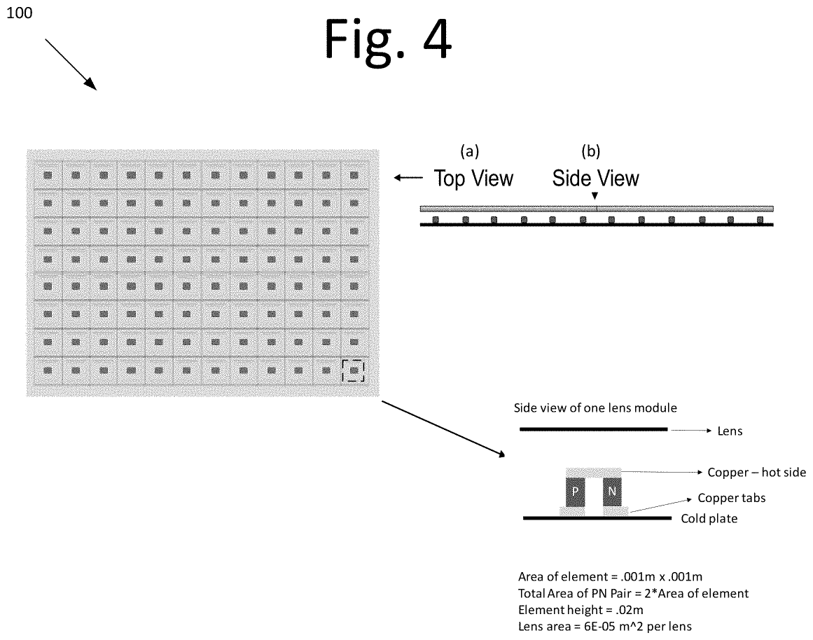

FIG. 4 is a diagram illustrating a multiple views (a)-(b) of thermoelectric generator 100, according to an embodiment of the present invention. In FIG. 4, views (a) and (b) show the top view and side view of cathode generator, respectively. Although a single lens may encompass multiple thermoelectric couple, some embodiments may have one lens per one thermoelectric couple. See, for example, FIG. 4, which shows a plurality of lenses associated with a corresponding one of a plurality of thermoelectric couples. This is more clearly illustrated in the side view of one lens 108, which is directly above a thermoelectric couple 102. In this embodiment, copper interconnects (or tabs) 110 are placed on both sides of thermoelectric couple 102. It should be noted that copper is used as the interconnect, since it electrically connects thermoelectric couple 102. The thermal couple pair (or thermocouple 102) represents one device, and each device can be interconnected on one panel substrate. The one-couple device vs. multiple couple device illustrates the flexibility of how the panel can be constructed. A 1 m² panel with 20X lens concentrator/cold plate (relative to the thermal couple area) may have ˜23800 one-couple devices in certain embodiments.

Further, the thickness of the panel including the honeycomb substrate (˜3 cm) and lens is comparable to current satellite solar arrays. Preliminary calculations show that a 1 m² panel with 23800 devices at 20X concentration/cold plate area can generate ˜340 W.

One or more embodiments generally pertain to an apparatus that combines a solar concentrator lens with a thermoelectric generator to harvest solar energy in space. The solar concentrator lens replaces the photovoltaics in the current state of the art.

In some additional embodiments, by facing the solar concentrator plate towards the sun, heat is radiated towards a hot plate. This allows heat to be radiated without the use of a heat sink, since the heat sink in these embodiments is space.

In certain embodiments, the apparatus includes a cold plate that has an area greater than the area of the thermoelectric generator. By increasing the area of the cold plate, heat is radiated more efficiently. It should be appreciated that preliminary calculations show up to ˜5% increasing in heat radiating efficiency.

In some further embodiments, the cold plate is a ceramic coated honeycomb, reducing the overall weight of the thermoelectric generator. It should be noted that weight savings can be up to 60 kg for 1 m²×1 cm panel.

In some embodiments, the hot plate has a high absorptance coating, reducing the overall weight while still providing high thermal efficiency. High absorption coating may be of any type of coating with a greater than 95% absorption. The coating may also be electrically insulating and may withstand temperatures greater than 700 C.

It will be readily understood that the components of various embodiments of the present invention, as generally described and illustrated in the figures herein, may be arranged and designed in a wide variety of different configurations. Thus, the detailed description of the embodiments of the present invention, as represented in the attached figures, is not intended to limit the scope of the invention as claimed, but is merely representative of selected embodiments of the invention.

The features, structures, or characteristics of the invention described throughout this specification may be combined in any suitable manner in one or more embodiments. For example, reference throughout this specification to “certain embodiments,” “some embodiments,” or similar language means that a particular feature, structure, or characteristic described in connection with the embodiment is included in at least one embodiment of the present invention. Thus, appearances of the phrases “in certain embodiments,” “in some embodiment,” “in other embodiments,” or similar language throughout this specification do not necessarily all refer to the same group of embodiments and the described features, structures, or characteristics may be combined in any suitable manner in one or more embodiments.

It should be noted that reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussion of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention can be practiced without one or more of the specific features or advantages of a particular embodiment. In other instances, additional features and advantages may be recognized in certain embodiments that may not be present in all embodiments of the invention.

One having ordinary skill in the art will readily understand that the invention as discussed above may be practiced with steps in a different order, and/or with hardware elements in configurations which are different than those which are disclosed. Therefore, although the invention has been described based upon these preferred embodiments, it would be apparent to those of skill in the art that certain modifications, variations, and alternative constructions would be apparent, while remaining within the spirit and scope of the invention. In order to determine the metes and bounds of the invention, therefore, reference should be made to the appended claims.

1. An extra-terrestrial based thermoelectric array, comprising:
a thermoelectric generator comprising a hot plate, wherein the thermoelectric generator converts heat directly into electrical energy;
a lens facing the sun on one side and facing the hot plate on the other side, wherein
the lens directly focuses heat from the sun onto the hot plate; and
a cold plate having a surface area larger than that of the hot plate dissipates heat into space and prevents a temperature of the hot plate from reaching above a melting temperature.

2. The extra-terrestrial based thermoelectric array of claim 1, wherein the hot plate is composed of a ceramic coated aluminum honeycomb.

3. The extra-terrestrial based thermoelectric array of claim 1, wherein the one or more thermoelectric couples, each of which comprise a NP junction being composed of tin selenide, are sandwiched between the hot plate and a cold plate.

4. The extra-terrestrial based thermoelectric array of claim 3, wherein the cold plate is composed of a ceramic coated aluminum honeycomb, the ceramic coated aluminum honeycomb is electrically insulative and radiates rejected or excess heat into space.

5. The extra-terrestrial based thermoelectric array of claim 3, wherein the cold plate faces the one or more thermoelectric couples on one side and space on another side.

6. The extra-terrestrial based thermoelectric array of claim 3, wherein the cold plate having the area greater than that of the one or more thermoelectric couples, increases a temperature difference between the hot plate and the cold plate.

7. The extra-terrestrial based thermoelectric array of claim 3, wherein the lens comprises an area greater than that of the hot plate, and further comprises an area same as an area of the cold plate.

8. The extra-terrestrial based thermoelectric array of claim 3, further comprising:
one or more interconnects placed on both sides of a corresponding one of the one or more thermoelectric couples configured to conduct an electric flow between NP junction forming an electric current.

9. The extra-terrestrial based thermoelectric array of claim 8, wherein the one or more interconnects are composed of copper to withstand temperature in excess of 700 degrees Celsius.

10. The extra-terrestrial based thermoelectric array of claim 8, further comprising:
a resistant adhesive being resistant to temperature in excess of 700 degrees Celsius configured to bond one or more interconnects to the cold plate.

11. An extra-terrestrial based thermoelectric array, comprising:
a thermoelectric generator comprising a hot plate, and is configured to convert heat directly into electrical energy;
one or more thermoelectric couples, each of which comprise a NP junction being composed of tin selenide, are sandwiched between the hot plate and a cold plate; and
a lens facing the sun on one side and facing the hot plate on the other side, wherein
the lens is configured to concentrate heat from the sun and onto the hot plate,
the cold plate having a surface area larger than that of the hot plate dissipates heat into space and prevents a temperature of the hot plate from reaching above a melting temperature.

12. The extra-terrestrial based thermoelectric array of claim 11, wherein the hot plate is composed of a ceramic coated aluminum honeycomb.

13. The extra-terrestrial based thermoelectric array of claim 11, wherein the cold plate is composed of a ceramic coated aluminum honeycomb, the ceramic coated aluminum honeycomb remains electrically insulative and radiates rejected or excess heat into space.

14. The extra-terrestrial based thermoelectric array of claim 11, wherein the cold plate faces the one or more thermoelectric couples on one side and space on another side.

15. The extra-terrestrial based thermoelectric array of claim 11, wherein the cold plate having the area greater than that of the one or more thermoelectric couples, increases a temperature difference between the hot plate and the cold plate.

16. The extra-terrestrial based thermoelectric array of claim 11, wherein the lens comprises an area greater than that of the hot plate, and further comprises an area same as an area of the cold plate.

17. The extra-terrestrial based thermoelectric array of claim 11, further comprising:
one or more interconnects placed on both sides of a corresponding one of the one or more thermoelectric couples configured to conduct an electric flow between NP junction forming an electric current.

18. The extra-terrestrial based thermoelectric array of claim 17, wherein the one or more interconnects are composed of copper to withstand temperature in excess of 700 degrees Celsius.

19. The extra-terrestrial based thermoelectric array of claim 17, further comprising:
a resistant adhesive being resistant to temperature in excess of 700 degrees Celsius configured to bond one or more interconnects to the cold plate.

20. A thermoelectric array, comprising:
a plurality of thermoelectric generators, each of which are comprised of a hot plate and are configured to convert heat directly into electrical energy;
one or more thermoelectric couples, each of which comprise a NP junction being composed of tin selenide, are sandwiched between a corresponding one of the plurality of hot plates and a cold plate; and
a plurality of lenses facing the sun on one side and facing the corresponding one of the plurality of hot plates on the other side, wherein
the lens is configured to concentrate heat from the sun and onto the corresponding one of the plurality of hot plates, and
the cold plate comprising an area to encompass each of the plurality of lenses and hot plates, dissipating heat into space and preventing a temperature of the hot plate from reaching above a melting temperature.
